(19) United States
(12) Patent Application Publication
(10) Pub. No.: US 2025/0364310 A1
(43) Pub. Date: Nov. 27, 2025

(54) SEMICONDUCTOR DEVICE ISOLATION STRUCTURE AND METHOD OF MANUFACTURING SAME

(71) Applicant: DB HiTek Co., Ltd., Bucheon-si (KR)

(72) Inventors: Joo Hyun LEE, Icheon-si (KR); Jun Hyeong KIM, Eumseong-gun (KR)

(21) Appl. No.: 18/756,945

(22) Filed: Jun. 27, 2024

(30) Foreign Application Priority Data
May 22, 2024 (KR) 10-2024-0066206

(51) Int. Cl. H01L 21/762; H01L 21/265; H01L 21/763; H01L 27/105; H01L 29/06

(52) U.S. Cl. CPC H01L 21/76224; H01L 21/763; H10D 62/107; H01L 21/2652; H10D 84/80

(57) ABSTRACT

In a semiconductor device isolation structure and a method of manufacturing the same, an ion implantation region is formed under a buried layer within a substrate in which a DTI region is formed to mitigate electric field concentration on a side on which the DTI region and the buried layer are in contact with each other or adjacent to each other, thereby enhancing isolation characteristics.

### CROSS-REFERENCE TO RELATED APPLICATION

The present application claims priority to Korean Patent Application No. 10-2024-0066206, filed May 22, 2024, the entire contents of which are incorporated herein for all purposes by this reference.

### BACKGROUND OF THE INVENTION

### Field of the Invention

The present disclosure relates generally to a semiconductor device isolation structure and a method of manufacturing the same. More particularly, the present disclosure relates to a semiconductor device isolation structure and a method of manufacturing the same, in which an ion implantation region is formed under a buried layer within a substrate in which a DTI region is formed to mitigate electric field concentration on a side on which the DTI region and the buried layer are in contact with each other or adjacent to each other, thereby enhancing isolation characteristics.

### Description of the Related Art

A BCDMOS (Bipolar-CMOS-DMOS) process requires a high breakdown voltage of 100V or more, and in accordance with this high voltage requirement, the process of forming a deep trench isolation (DTI) region is used to prevent an increase in leakage current through electrical isolation between adjacent devices. FIG. 1 is a cross-sectional view illustrating a conventional semiconductor device isolation structure, and hereinafter, the conventional semiconductor device isolation structure and problems thereof will be described in detail with reference to FIG. 1.

Referring to FIG. 1, in a conventional semiconductor device, a buried layer 910 of a second conductivity type is formed at a predetermined depth within a substrate 901. Additionally, a DTI region 921 and 923 is formed from the surface of the substrate 901 to a predetermined depth. The DTI region may include a sidewall 921 and a polysilicon material 923 that fills a deep trench on the sidewall 921. When using the structure of the DTI region 920 like this, an electric field is concentrated due to increase in the operating voltage of the device at a point where the buried layer 910 and the DTI region 921 and 923 meet each other, thereby deteriorating isolation characteristics.

In order to solve this problem, the inventors of the present invention is intended to propose a new semiconductor device isolation structure with an improved structure and a method of manufacturing the same, and details thereof will be described later.

### DOCUMENT OF RELATED ART

(Patent Document) Korean Patent Application Publication No. 10-2003-0000592 ‘METHOD FOR MANUFACTURING SEMICONDUCTOR DEVICE WITH STI/DTI STRUCTURE’

### SUMMARY OF THE INVENTION

Accordingly, the present disclosure has been made keeping in mind the above problems occurring in the related art, and the present disclosure is intended to propose a semiconductor device isolation structure and a method of manufacturing the same, in which in which an ion implantation region is formed under a buried layer within a substrate in which a DTI region is formed to mitigate electric field concentration on a point on which the buried layer and the DTI region are in contact with each other or adjacent to each other, thereby enhancing isolation characteristics.

In addition, the present disclosure is intended to propose a semiconductor device isolation structure and a method of manufacturing the same, in which the ion implantation region is pre-formed in the substrate before the buried layer is formed so that the ion implantation region is easily formed at a desired depth in the substrate.

Additionally, the present disclosure is intended to provide a semiconductor device isolation structure and a method of manufacturing the same, wherein a gap-fill region is formed through a substrate under a deep trench by epitaxial growth, thereby enabling an easy gap-fill process within the deep trench.

The present disclosure may be implemented through embodiments with the following configuration to achieve the purposes described above.

According to an embodiment of the present disclosure, a semiconductor device isolation structure according to the present disclosure includes: a substrate; a DTI region extending to a predetermined depth from a surface of the substrate; a buried layer of a second conductivity type located within the substrate; and an ion implantation region of a second conductivity type located under the buried layer within the substrate.

According to another embodiment of the present disclosure, in the semiconductor device isolation structure according to the present disclosure, the ion implantation region may be a low-concentration doped region of a second conductivity-type impurity compared to the buried layer.

According to another embodiment of the present disclosure, in the semiconductor device isolation structure according to the present disclosure, the ion implantation region may be formed within the substrate before the buried layer is formed.

According to another embodiment of the present disclosure, in the semiconductor device isolation structure according to the present disclosure, the DTI region may include: a liner in contact with a portion of the substrate adjacent thereto; a sidewall located on the liner; and a gap-fill region located on the sidewall.

According to another embodiment of the present disclosure, in the semiconductor device isolation structure according to the present disclosure, the gap-fill region may include polysilicon doped with a first conductivity-type impurity.

According to another embodiment of the present disclosure, in the semiconductor device isolation structure according to the present disclosure, the gap-fill region may have a lower surface in contact with a portion of the substrate under the gap-fill region.

According to another embodiment of the present disclosure, the semiconductor device isolation structure according to the present disclosure may further include: a deep well region located above the buried layer within the substrate.

According to another embodiment of the present disclosure, the semiconductor device isolation structure according to the present disclosure may further include: a high voltage well region located between the buried layer within the substrate and the deep well region.

According to another embodiment of the present disclosure, a semiconductor device isolation structure according to the present disclosure includes: a substrate; a first epitaxial layer located on the substrate; an ion implantation region of a second conductivity type located within the substrate; a buried layer of a second conductivity type having at least a portion located in the first epitaxial layer, with the buried layer being located on the ion implantation region; a second epitaxial layer located on the first epitaxial layer; and a DTI region extending from a surface of the second epitaxial layer to a predetermined depth within the substrate.

According to another embodiment of the present disclosure, in the semiconductor device isolation structure according to the present disclosure, the DTI region may include: a liner in contact with a portion of the substrate adjacent thereto and comprising an insulating material; a sidewall located on the liner and comprising an insulating material; and a gap-fill region located on the sidewall.

According to another embodiment of the present disclosure, in the semiconductor device isolation structure according to the present disclosure, the gap-fill region may have a side in contact with the substrate.

According to another embodiment of the present disclosure, in the semiconductor device isolation structure according to the present disclosure, the ion implantation region may be located at a predetermined depth spaced apart from an upper surface of the substrate.

According to another embodiment of the present disclosure, in the semiconductor device isolation structure according to the present disclosure, the buried layer may be located on a surface side of the substrate and within the first epitaxial layer.

According to an embodiment of the present disclosure, a method of manufacturing a semiconductor device isolation structure according to the present disclosure includes: forming an ion implantation region in a substrate; forming a first epitaxial layer on the substrate in which the ion implantation region is formed; forming a buried layer in the first epitaxial layer; forming one or more additional epitaxial layers on the first epitaxial layer; forming a multilayer film on a top epitaxial layer; exposing a portion of the top epitaxial layer by etching one side of the multilayer film; forming a deep trench by etching the additional epitaxial layers, the first epitaxial layer, and the substrate; and forming a DTI region within the deep trench.

According to another embodiment of the present disclosure, in the method of manufacturing a semiconductor device isolation structure according to the present disclosure, the forming of the DTI region may include: forming a first insulating film on an inner wall and a lower surface of the deep trench; forming a second insulating film on the first insulating film; and forming a liner and a sidewall by etching back the first insulating film and the second insulating film.

According to another embodiment of the present disclosure, in the method of manufacturing a semiconductor device isolation structure according to the present disclosure, at least a portion of each of the first insulating film and the second insulating film on the lower surface of the deep trench may be removed during the etching back.

According to another embodiment of the present disclosure, in the method of manufacturing a semiconductor device isolation structure according to the present disclosure, the forming of the DTI region may further include forming a gap-fill region on the sidewall within the deep trench, wherein the forming of the gap-fill region may include: forming a first material layer within the deep trench; doping a first conductivity-type impurity into the first material layer; forming a second material layer on the first material layer; and doping a first conductivity-type impurity into the second material layer.

According to another embodiment of the present disclosure, in the method of manufacturing a semiconductor device isolation structure according to the present disclosure, the first material layer may include polysilicon or amorphous silicon.

According to another embodiment of the present disclosure, in the method of manufacturing a semiconductor device isolation structure according to the present disclosure, the forming of the DTI region may further include forming a gap-fill region on the sidewall within the deep trench, wherein the forming of the gap-fill region may include gap-filling a gap-fill material doped with a first conductivity-type impurity within the deep trench.

According to another embodiment of the present disclosure, in the method of manufacturing a semiconductor device isolation structure according to the present disclosure, the forming of the DTI region may further include forming a gap-fill region on the sidewall within the deep trench, wherein the forming of the gap-fill region may include forming one or more epitaxial growth regions through a portion of the substrate under the deep trench and doping a first conductivity-type impurity into each of the epitaxial growth regions.

The present disclosure has the following effects according to the structure described above.

According to the present disclosure, the ion implantation region is formed under the buried layer within the substrate in which the DTI region is formed to mitigate electric field concentration on a point on which the buried layer and the DTI region are in contact with each other or adjacent to each other, thereby enhancing isolation characteristics.

In addition, according to the present disclosure, the ion implantation region is pre-formed in the substrate before the buried layer is formed, thereby allowing the ion implantation region to be easily formed at a desired depth in the substrate.

Furthermore, according to the present disclosure, the gap-fill region is formed through a side of the substrate under the deep trench by epitaxial growth, thereby enabling an easy gap-fill process within the deep trench.

Meanwhile, it should be added that even if effects are not explicitly mentioned here, the effects described in the following specifications and potential effects thereof expected by the technical features of the present disclosure are treated as if they were described in the specifications of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional semiconductor device isolation structure;

FIG. 2 is a cross-sectional view illustrating a semiconductor device isolation structure according to an embodiment of the present disclosure; and

FIGS. 3 to 16 are cross-sectional views illustrating a method of manufacturing the semiconductor device isolation structure according to the embodiment of the present disclosure.

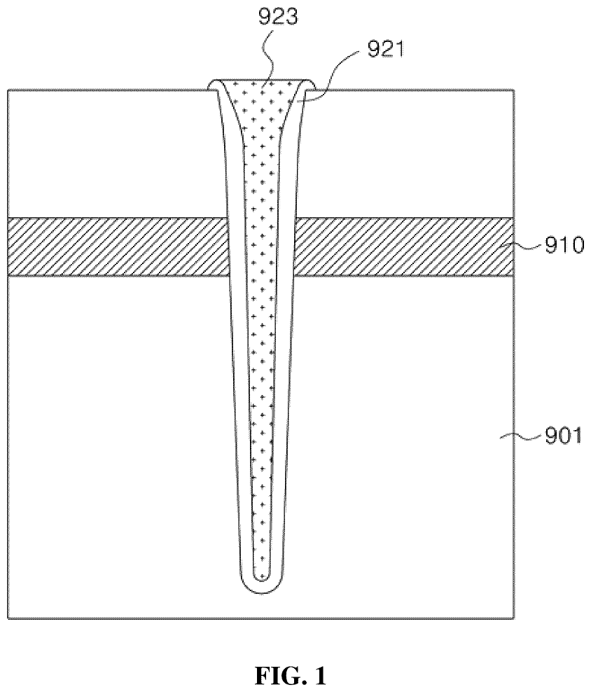

### DETAILED DESCRIPTION OF THE INVENTION

Hereinafter, embodiments of the present disclosure will be described in more detail with reference to the attached drawings. The embodiments of the present disclosure may be modified in various forms, and the scope of the present disclosure should not be construed as limited to the embodiments below and should be interpreted on the basis of the matters stated in the claims. In addition, these embodiments are only provided as a reference to more completely explain the present disclosure to those with average knowledge in the art.

Hereinafter, when a first component (or layer) is described as being placed on a second component (or layer), it should be noted that the first component may be placed directly on the second component, or there may be a third component(s) or layer(s) located between the corresponding components. Additionally, when the first component is expressed as being placed directly on or above the second component, no other component(s) are located between the corresponding components. In addition, being located on the ‘upper part’, ‘lower part’, ‘upper side’, ‘lower side’ or ‘one side’ or ‘side surface’ of the first component means a relative positional relationship.

Additionally, terms such as first, second, and third, etc. may be used to describe various items such as various elements, regions, and/or parts, but the items are not limited by these terms.

Additionally, it should be noted that in a case in which a specific embodiment can be implemented differently, a specific process sequence may be different from a process sequence to be described below. For example, two processes described sequentially may be performed substantially at the same time or may be performed in the opposite order.

A term metal-oxide semiconductor (MOS) used below is a general term, and ‘M’ is not limited only to metal and may be composed of various types of conductors. In addition, ‘S’ may be a substrate or a semiconductor structure, and ‘O’ is not limited to oxides and may include various types of organic or inorganic substances.

Additionally, the conductivity types or doped regions of components may be defined as ‘P type’ or ‘N type’ depending on main carrier characteristics, but this is only for convenience of explanation, and the technical idea of the present disclosure is not limited to what is illustrated. For example, hereinafter ‘P type’ or ‘N type’ will be used as the more general terms ‘first conductivity type’ or ‘second conductivity type’, wherein the first conductivity type means P type and the second conductivity type means N type.

In addition, ‘high concentration’ and ‘low concentration’, which express the doping concentration of an impurity region, should be understood to mean the relative doping concentrations of one component and another component.

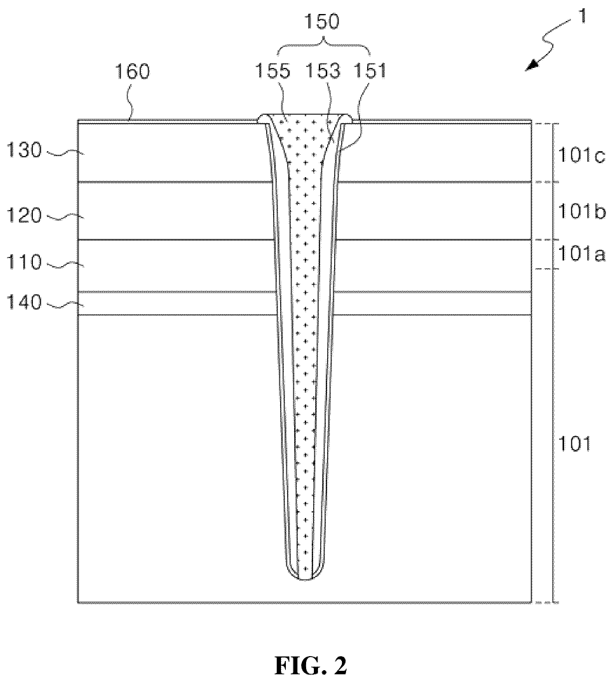

FIG. 2 is a cross-sectional view illustrating a semiconductor device isolation structure according to an embodiment of the present disclosure.

Hereinafter, a semiconductor device isolation structure 1 according to the embodiment of the present disclosure will be described in detail with reference to the attached drawings.

Referring to FIG. 2, the present disclosure relates generally to a semiconductor device isolation structure. More particularly, the present disclosure relates to a semiconductor device isolation structure, in which an ion implantation region is formed under a buried layer within the substrate in which the DTI region is formed to mitigate electric field concentration on a side on which the DTI region and the buried layer are in contact with each other or adjacent to each other, thereby enhancing isolation characteristics.

The formation depth of the DTI region 150 described below is preferably approximately 30 μm or more and 40 μm or less from the surface of the substrate 101, but it should be noted that the scope of the present disclosure is not limited by the above numerical range.

In the semiconductor device isolation structure 1 according to the embodiment of the present disclosure, the substrate 101 may be formed first. A well region used as an active region may be formed on the substrate 101, and this active region may be defined by an STI region (not shown) serving as a device separation film. In addition, the substrate 101 may be a substrate doped with a first conductivity type, a P-type diffusion region may be disposed within the substrate, or a P-type epitaxial layer may be epitaxially grown on the substrate. Preferably, a first epitaxial layer 101a, a second epitaxial layer 101b, and a third epitaxial layer 101c may be formed sequentially on the substrate 101, but the scope of the present disclosure is not limited thereto. Hereinafter, except cases which the substrate 101 and the epitaxial layers 101a to 101c are clearly distinguished, when referring to the substrate 101, it is understood to include one or more epitaxial layers on the substrate.

In addition, a buried layer 110 may be formed in the substrate 101. For example, the buried layer 110, which is the high-concentration doped region of a second conductivity-type impurity, may be formed at a predetermined depth in the substrate 101. Preferably, the buried layer 110 may be formed in the substrate 101 and in the first epitaxial layer 101a on the substrate 101. Additionally, the buried layer 110 may be in contact with the outer wall of the DTI region 150 adjacent thereto or may be formed on a side adjacent to the DTI region 150, but there is no separate limitation thereon. In addition, a high voltage well region 120 may be formed within the substrate 101. For example, the high voltage well region 120, which is a second conductivity-type impurity doped region, may be formed on the buried layer 110 within the substrate 101. Preferably, the high voltage well region 120 may be formed within the second epitaxial layer 101b above the substrate 101. In addition, the high voltage well region 120 may have a side connected to the buried layer 110. It should be noted that the described high voltage well region 120 is not an essential element of the present disclosure and may be omitted in some cases.

In addition, a deep well region 130 may be formed on the high voltage well region 120 in the substrate 101. The deep well region 130 may have one side connected to the high voltage well region 120 or the buried layer 110 and, for example, may be a second conductivity-type impurity doped region. Preferably, the deep well region 130 may be formed within the third epitaxial layer 101c above the substrate 101. In addition, a drain region (not shown) may be formed within the deep well region 130. The high voltage well region 120 and the deep well region 130 which are described above may be in contact with the outer wall of the adjacent DTI region 150 or may be formed on a side adjacent to the DTI region 150, but there is no separate limitation thereon.

In addition, the ion implantation region 140 may be formed under the buried layer 110 within the substrate 101. The ion implantation region 140, for example, may have an upper surface formed to be in contact with the lower surface of the buried layer 110, and may be a second conductivity-type impurity doped region. Furthermore, for example, the ion implantation region 140 is preferably a low-concentration doped region of a second conductivity-type impurity compared to the buried layer 110, the high voltage well region 120, and the deep well region 130. In addition, the ion implantation region 140 is preferably formed before the buried layer 110 is formed within the substrate 101. Accordingly, by forming the ion implantation region 140 within the substrate 101, electric field concentration on a point on which the buried layer 110 and the DTI region 150 are in contact with each other or are adjacent to each other may be mitigated, thereby improving the isolation characteristics of a semiconductor device. In addition, the ion implantation region 140 is preferably formed in the substrate 101 under the first epitaxial layer 101a. For example, the ion implantation region 140 may be formed at a predetermined depth spaced apart from the surface of the substrate 101.

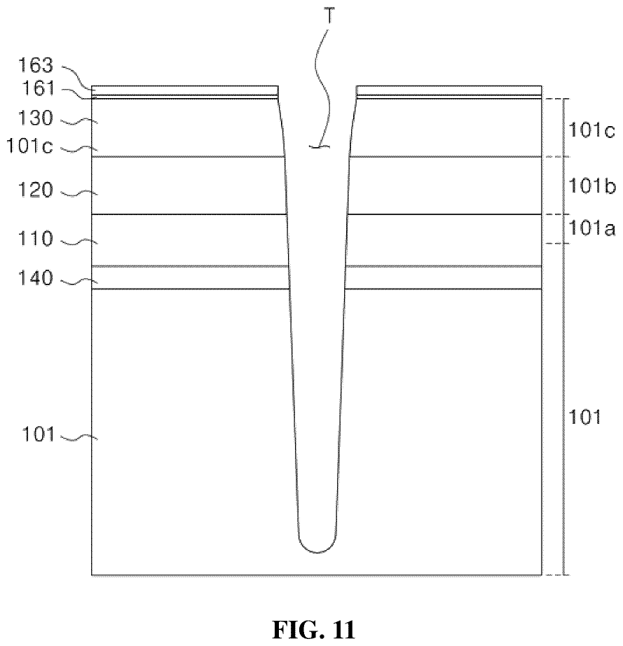

In addition, the DTI region 150 may be formed within the substrate 101. The DTI region 150 is, for example, a region extending from the upper surface of the third epitaxial layer 101c to a predetermined depth within the substrate 101, and a lateral wall of the DTI region 150 may extend in a vertical direction or may be formed to be inclined to be narrower gradually downward. The DTI region 150 may include a liner 151. The liner 151 may be formed on the lateral wall of the DTI region 150 and may, for example, include an insulating material such as an oxide film. In addition, the DTI region 150 may further include a sidewall 153. The sidewall 153 is formed on the liner 151 within a deep trench T (see FIG. 11) and may include, for example, an oxide film. The DTI region 150 may further include a gap-fill region 155.

The gap-fill region 155, which is a region that gap-fills the deep trench T on the sidewall 153, may include an electrically conductive material, for example, polysilicon. In addition, the gap-fill region 155 may have a lower surface whose side is in contact with the substrate 101 at the lower side thereof. That is, the lower surface of the DTI region 150 is preferably formed to have a side that is not blocked by the liner 151 and the sidewall 153 so that the gap-fill region 155 is in direct contact with the substrate 101. In addition, it is more preferable that the gap-fill region 155 is doped with a first conductivity-type impurity and used as an electrode.

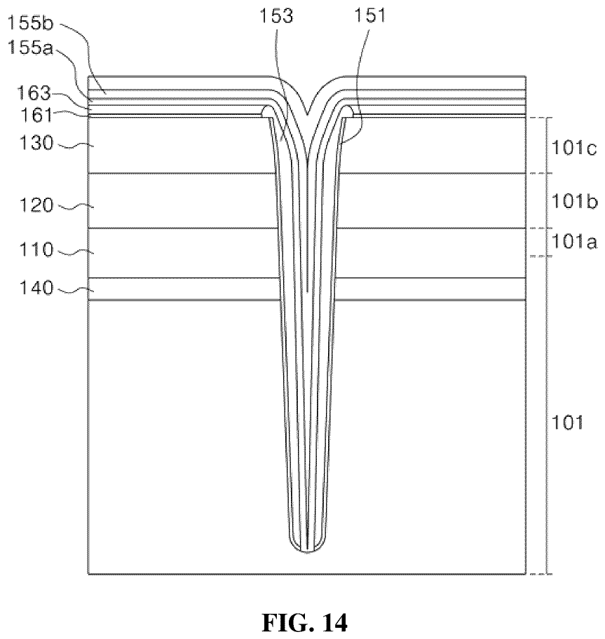

Below, the method of forming the gap-fill region 155 within the DTI region 150 will be described in detail. According to a first embodiment (see FIG. 14), multiple gap-fill material layers 155a to 155b are formed within the deep trench T in which the sidewall 153 is formed. That is, a first material layer 155a is formed within the deep trench T in which the sidewall 153 is formed, the first conductivity-type impurity is ion-implanted into the first material layer 155a, a second material layer 155b is formed on the first material layer 155a, and the first conductivity-type impurity is ion-implanted into the second material layer 155b. Next, by performing a heat treatment process, the gap-fill region 155 doped with the first conductivity type impurities may be formed in the DTI region 150. In this case, the individual material layers 155a and 155b may include polysilicon or amorphous silicon (Si). In addition, two or more individual material layers may be formed, and there is no separate limit on the number thereof.

According to a second embodiment (see FIG. 14), the first material layer 155a doped with the first conductivity-type impurity may be gap-filled within the deep trench T in which the sidewall 153 is formed, the second material layer 155b doped with the first conductivity-type impurity may be formed on the first material layer 155a, and then heat treatment process may be performed to form the gap-fill region 155. In this case, the individual material layers 155a and 155b may include polysilicon or amorphous silicon (Si). In addition, two or more individual material layers may be formed, and there is no separate limit on the number thereof.

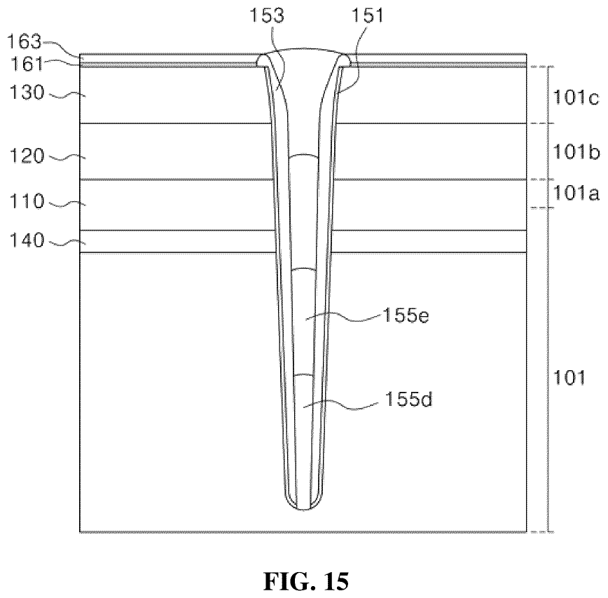

According to a third embodiment (see FIG. 15), one or more epitaxial growth regions are formed through a portion of the substrate 101 under the deep trench T in which the sidewall 153 is formed, and the first conductivity-type impurity is ion-implanted into individual epitaxial growth regions. Afterwards, the gap-fill region 155 may be formed by performing a heat treatment process. For example, after forming a first epitaxial growth region 155d on the lowest part of the deep trench T, the first conductivity-type impurity is ion-implanted into the first epitaxial growth region 155d. Afterwards, a second epitaxial growth region 155c is formed on the first epitaxial growth region 155d, and the first conductivity-type impurity is ion-implanted into the second epitaxial growth region 155c. The gap-fill region 155 may be formed by repeating the above process to gap-fill all of the deep trench T and performing a heat treatment process. In this case, there is no separate limitation on the number of epitaxial growth regions.

Next, an insulating film layer 160 is formed on the substrate 101 or the third epitaxial layer 101c. The insulating film layer 160 may, for example, be formed as a multilayer film of an oxide film and a nitride film, but there is no separate limitation thereon.

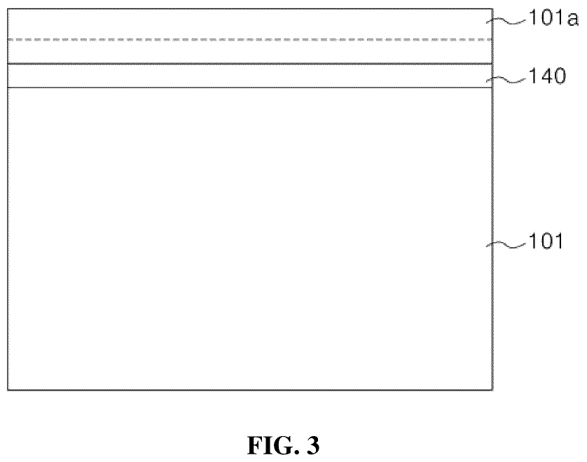

FIGS. 3 to 16 are cross-sectional views illustrating a method of manufacturing the semiconductor device isolation structure according to the embodiment of the present disclosure.

Hereinafter, the method of manufacturing the semiconductor device isolation structure according to the embodiment of the present disclosure will be described in detail with reference to the attached drawings.

Referring to FIG. 3, first, the ion implantation region 140 may be formed within the substrate 101. The ion implantation region 140 may be formed, for example, by ion-implantation of a second conductivity-type impurity into the substrate 101. The ion implantation region 140 may be formed on the surface of the substrate 101 or may be formed at a predetermined depth within the substrate 101. Next, the first epitaxial layer 101a is formed on the substrate 101 in which the ion implantation region 140 is formed.

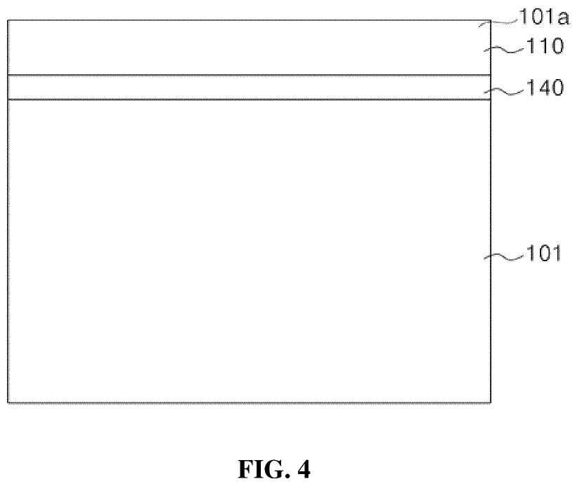

Next, referring to FIG. 4, the buried layer 110 is formed in the first epitaxial layer 101a. The buried layer 110, which is a second conductivity-type impurity doped region, is preferably a high-concentration doped region of a second conductivity-type impurity compared to the ion implantation region 140 described above. In addition, the buried layer 110 is located on the ion implantation region 140. As described, according to an embodiment of the present disclosure, it may be seen that after forming the ion implantation region 140 within the substrate 101, the first epitaxial layer 101a is formed and the buried layer 110 is formed within the first epitaxial layer 101a.

Unlike this, when the buried layer 110 is formed within the substrate 101, and the ion implantation region 140 is formed in an internal portion of the substrate 101 under the buried layer 110, due to high ion implantation energy required during the formation of the ion implantation region 140, it is inevitable that it is difficult to form the ion implantation region 140 at a desired depth within the substrate 101.

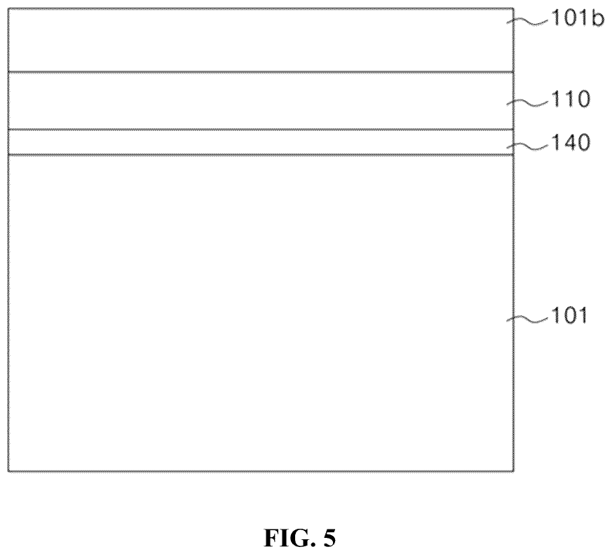

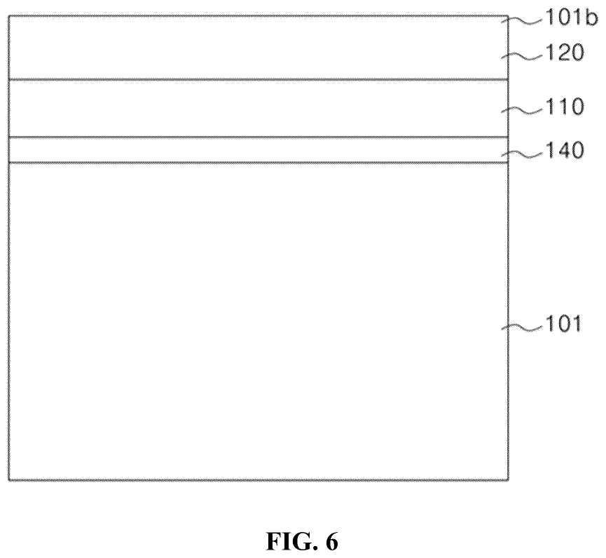

Referring to FIG. 5, after forming the buried layer 110, the second epitaxial layer 101b is formed on the first epitaxial layer 101a. In addition, referring to FIG. 6, the high voltage well region 120 may be formed within the second epitaxial layer 101b. The high voltage well region 120 is, for example, a second conductivity-type impurity doped region, and may be formed by the ion implantation of a second conductivity-type impurity into the second epitaxial layer 101b. However, as described above, the high voltage well region 120 is not an essential component of the present disclosure, and when the high voltage well region 120 is not formed, the third epitaxial layer 101c to be described later may be directly formed on the first epitaxial layer 101a.

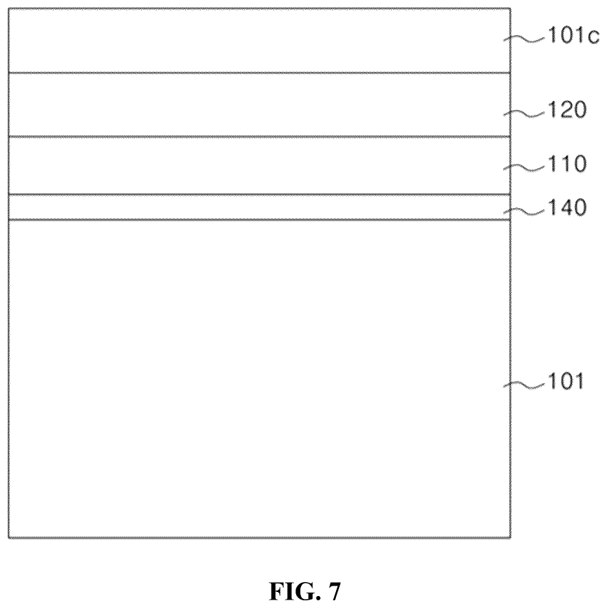

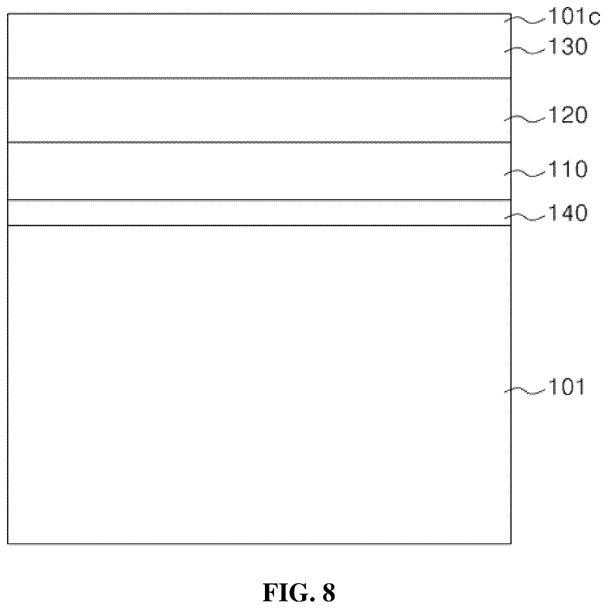

Referring to FIG. 7, after forming the high voltage well region 120, the third epitaxial layer 101c is formed on the second epitaxial layer 101b. In addition, referring to FIG. 8, the deep well region 130 may be formed in the third epitaxial layer 101c. The deep well region 130 is, for example, a second conductivity-type impurity doped region, and may be formed by the ion implantation of a second conductivity-type impurity into the third epitaxial layer 101c.

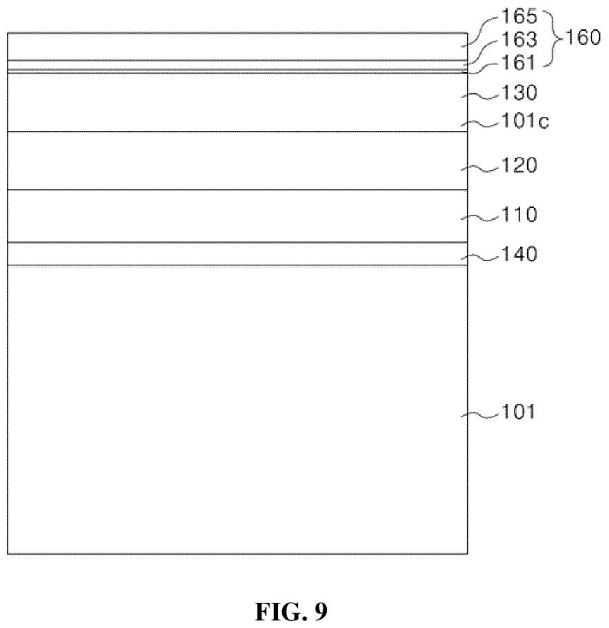

Next, referring to FIG. 9, a multilayer film may be formed on the third epitaxial layer 101c. To illustrate the process of forming the multilayer film, an oxide film 161 may be formed on the third epitaxial layer 101c, an etch stop film 163 may be formed on the oxide film 161, and a hard mask may be formed on the etch stop film 163. The etch stop film 163 is an etch stop film in an etch-back process and a CMP process to be described later, and may include, for example, a nitride film. Additionally, the hard mask 165 may include, for example, an oxide film and a TEOS film formed by using low pressure chemical vapor deposition (LPCVD), but the present disclosure is not limited thereto.

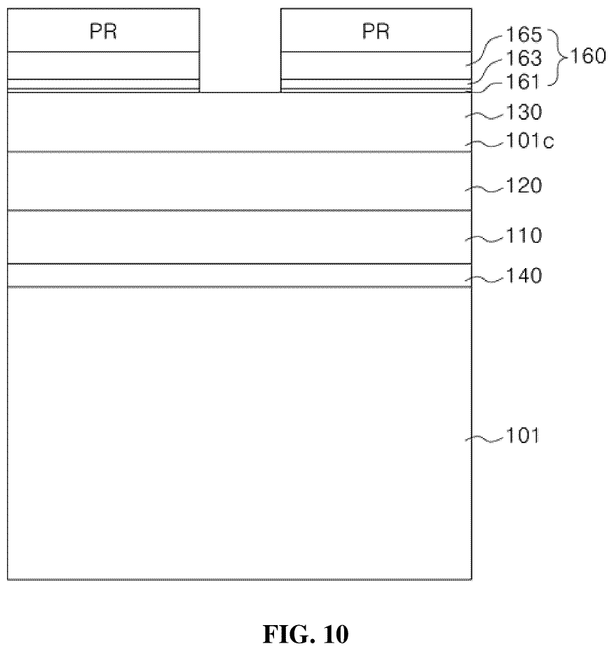

Next, referring to FIG. 10, a part of the multilayer film at a side on which the DTI region 150 will be formed is etched. For example, a photoresist film PR may be formed on the hard mask 165, and the photoresist film PR may be etched to be open at the part thereof, and the hard mask 165, the etch stop film 163, and the oxide film 161 may be sequentially etched.

Next, referring to FIG. 11, a side of each of the third epitaxial layer 101c, the second epitaxial layer 101b, the first epitaxial layer 101a, and the substrate 101 is etched to be open to form the deep trench T. In this case, the deep trench T may be formed to a depth of approximately 30 μm or more and 40 μm or less from the surface of the third epitaxial layer 101c. In this process, the hard mask 165 may be removed together or at least partially removed. Afterwards, the photoresist film PR is removed.

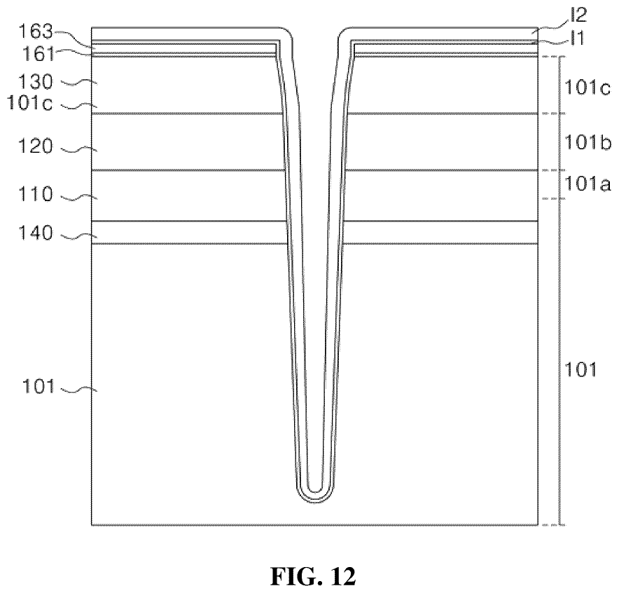

Next, referring to FIG. 12, a first insulating film I1 may be formed on the inner wall and lower surface of the deep trench T, and a second insulating film 12 may be formed on the first insulating film I1. In this case, the first insulating film I1 and the second insulating film 12 may be deposited even on the third epitaxial layer 101c.

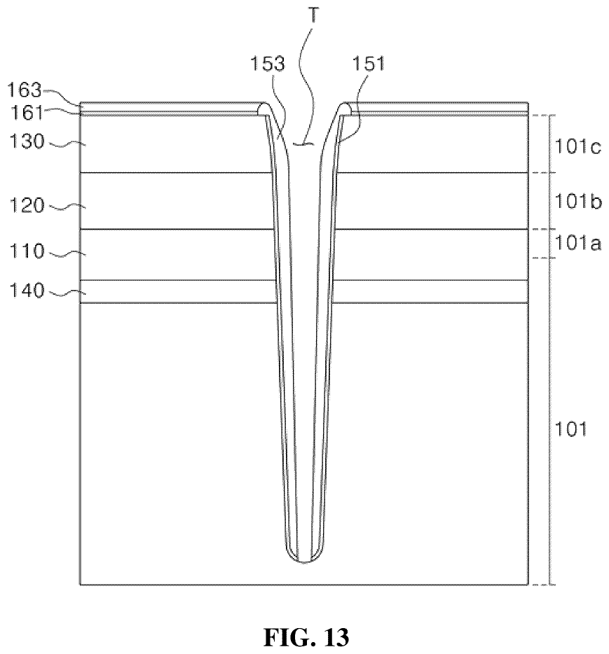

In addition, referring to FIG. 13, by performing an etch-back process on the first insulating film I1 and the second insulating film 12, the liner 151 and the sidewall 153 may be formed. As described above, a side of each of the first insulating film I1 and the second insulating film 12 located on the lower surface of the deep trench T may also be removed. That is, the lower surface of the deep trench T may have a portion that is not covered by the liner 151 and the sidewall 153.

Next, the gap-fill region 155 is formed on the sidewall 153 within the deep trench T.

According to the first embodiment (see FIG. 14), the multiple gap-fill material layers 155a to 155b are formed within the deep trench T in which the sidewall 153 is formed. That is, the first material layer 155a is formed within the deep trench T in which the sidewall 153 is formed, the first conductivity-type impurity is ion-implanted into the first material layer 155a, the second material layer 155b is formed on the first material layer 155a, and the first conductivity-type impurity is ion-implanted into the second material layer 155b. After that, by performing a heat treatment process, the gap-fill region 155 doped with the first conductivity type impurities may be formed in the DTI region 150. In this case, the individual material layers 155a and 155b may include polysilicon or amorphous silicon (Si). In addition, two or more individual material layers may be formed, and there is no separate limit on the number thereof.

According to the second embodiment (see FIG. 14), the first material layer 155a doped with the first conductivity-type impurity may be gap-filled within the deep trench T in which the sidewall 153 is formed, the second material layer 155b doped with the first conductivity-type impurity may be formed on the first material layer 155a, and then a heat treatment process may be performed to form the gap-fill region 155. In this case, the individual material layers 155a and 155b may include polysilicon or amorphous silicon (Si). In addition, two or more individual material layers may be formed, and there is no separate limit on the number thereof.

According to the third embodiment (see FIG. 15), one or more epitaxial growth regions are formed through a portion of the substrate 101 under the deep trench T in which the sidewall 153 is formed, and the first conductivity-type impurity is ion-implanted into the individual epitaxial growth regions. Next, by performing a heat treatment process, the gap-fill region 155 may be formed. For example, after forming the first epitaxial growth region 155d on the lowest part of the deep trench T, the first conductivity-type impurity is ion-implanted into the first epitaxial growth region 155d. Next, the second epitaxial growth region 155e is formed on the first epitaxial growth region 155d, and the first conductivity-type impurity is ion-implanted into the second epitaxial growth region 155e. The gap-fill region 155 may be formed by repeating the above process to gap-fill all of the deep trench T and performing a heat treatment process. In this case, there is no separate limitation on the number of the epitaxial growth regions.

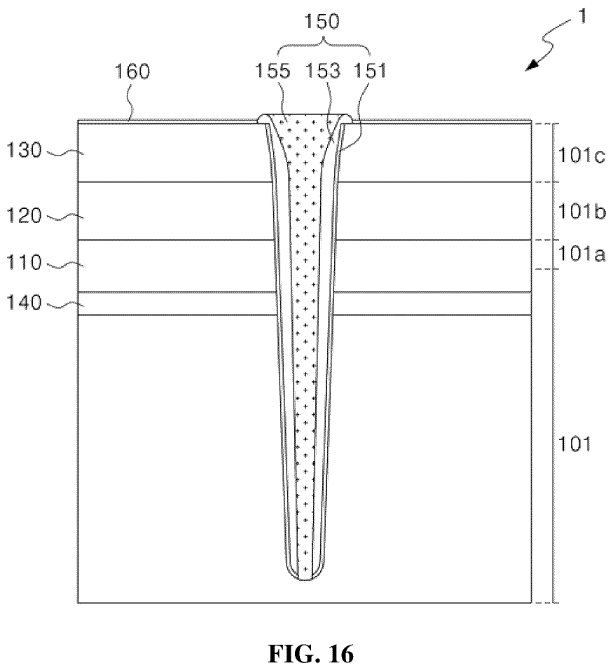

Next, referring to FIG. 16, by performing a CMP process, the upper side of the gap-fill region 155 may be planarized. Next, the etch stop film 163 is removed.

The detailed description above is illustrative of the present disclosure. Additionally, the foregoing describes preferred embodiments of the present disclosure, and the present disclosure may be used in various other combinations, modifications, and circumstances thereof. That is, changes or modifications may be made within the scope of the concept of the invention disclosed in this specification, a scope equivalent to the written disclosure, and/or the scope of technology or knowledge in the art. The above-described embodiments illustrate the best state for implementing the technical idea of the present disclosure, and various changes thereof required for specific application fields and uses of the present disclosure are also possible. Accordingly, the above detailed description of the invention is not intended to limit the present disclosure to the disclosed embodiments.

What is claimed is:

1. A semiconductor device isolation structure comprising:
a substrate;
a DTI region extending to a predetermined depth within the substrate from a surface of the substrate;
a buried layer of a second conductivity type disposed within the substrate; and
an ion implantation region of a second conductivity type disposed under the buried layer within the substrate.

2. The semiconductor device isolation structure of claim 1, wherein the ion implantation region has a low-concentration doped region of a second conductivity-type impurity compared to the buried layer.

3. The semiconductor device isolation structure of claim 1, wherein the ion implantation region is formed within the substrate before the buried layer is formed.

4. The semiconductor device isolation structure of claim 1, wherein the DTI region comprises:
a liner disposed in contact with a portion of the substrate adjacent thereto;
a sidewall disposed on the liner, and
a gap-fill region disposed on the sidewall.

5. The semiconductor device isolation structure of claim 4, wherein the gap-fill region comprises polysilicon doped with a first conductivity-type impurity.

6. The semiconductor device isolation structure of claim 4, wherein the gap-fill region has a lower surface in contact with a portion of the substrate under the gap-fill region.

7. The semiconductor device isolation structure of claim 6, further comprising:
a deep well region disposed above the buried layer within the substrate.

8. The semiconductor device isolation structure of claim 7, further comprising:
a high voltage well region disposed between the buried layer and the deep well region within the substrate.

9. A semiconductor device isolation structure comprising:
a substrate;
a first epitaxial layer disposed on the substrate;
an ion implantation region of a second conductivity type disposed within the substrate;
a buried layer of a second conductivity type having at least a portion disposed in the first epitaxial layer, the buried layer being disposed on the ion implantation region;
a second epitaxial layer disposed on the first epitaxial layer; and
a DTI region extending from a surface of the second epitaxial layer to a predetermined depth within the substrate.

10. The semiconductor device isolation structure of claim 9, wherein the DTI region comprises:
a liner disposed in contact with a portion of the substrate adjacent thereto, the liner comprising an insulating material;
a sidewall disposed on the liner and comprising an insulating material; and
a gap-fill region disposed on the sidewall.

11. The semiconductor device isolation structure of claim 10, wherein the gap-fill region has a side in contact with the substrate.

12. The semiconductor device isolation structure of claim 9, wherein the ion implantation region is disposed at a predetermined depth spaced apart from an upper surface of the substrate.

13. The semiconductor device isolation structure of claim 12, wherein the buried layer is disposed at a surface side of the substrate, the at least the portion of the buried layer being disposed within the first epitaxial layer.

14. A method of manufacturing a semiconductor device isolation structure, the method comprising:
forming an ion implantation region in a substrate;
forming a first epitaxial layer on the substrate in which the ion implantation region is formed;
forming a buried layer in the first epitaxial layer;
forming one or more additional epitaxial layers on the first epitaxial layer;
forming a multilayer film on a top epitaxial layer of the one or more additional epitaxial layers;
exposing a portion of the top epitaxial layer by etching one side of the multilayer film;
forming a deep trench by etching the one or more additional epitaxial layers, the first epitaxial layer, and the substrate; and
forming a DTI region within the deep trench.

15. The method of claim 14, wherein the forming of the DTI region comprises:
forming a first insulating film on an inner wall and a lower surface of the deep trench;
forming a second insulating film on the first insulating film; and
forming a liner and a sidewall by etching back the first insulating film and the second insulating film, respectively.

16. The method of claim 15, wherein at least a portion of each of the first insulating film and the second insulating film on the lower surface of the deep trench is removed during the etching back.

17. The method of claim 15,
wherein the forming of the DTI region further comprises forming a gap-fill region on the sidewall within the deep trench, and
wherein the forming of the gap-fill region comprises:
forming a first material layer within the deep trench;
doping a first conductivity-type impurity into the first material layer;
forming a second material layer on the first material layer; and
doping a first conductivity-type impurity into the second material layer.

18. The method of claim 17, wherein the first material layer comprises polysilicon or amorphous silicon.

19. The method of claim 15,
wherein the forming of the DTI region further comprises forming a gap-fill region on the sidewall within the deep trench, and
wherein the forming of the gap-fill region comprises gap-filling a gap-fill material doped with a first conductivity-type impurity within the deep trench.

20. The method of claim 16,
wherein the forming of the DTI region further comprises forming a gap-fill region on the sidewall within the deep trench, and
wherein the forming of the gap-fill region comprises forming one or more epitaxial growth regions through a portion of the substrate under the deep trench and doping a first conductivity-type impurity into each of the one or more epitaxial growth regions.
